(19) United States
(12) Patent Application Publication
(10) Pub. No.: US 2026/0112438 A1
(43) Pub. Date: Apr. 23, 2026

(54) MEMORY MODULE INCLUDING A CLOCK DRIVER SUPPORTING DYNAMIC FREQUENCY SCALING, TRAINING METHOD OF MEMORY DEVICE, AND OPERATING METHOD OF MEMORY MODULE

(71) Applicant: Samsung Electronics Co., Ltd., Suwon-si (KR)

(72) Inventors: Min-Gyo Jeong, Suwon-si (KR); Jinhun Jeong, Suwon-si (KR); Ki-Seok Park, Suwon-si (KR); Junho Jung, Suwon-si (KR)

(21) Appl. No.: 19/360,224

(22) Filed: Oct. 16, 2025

(30) Foreign Application Priority Data
Oct. 22, 2024 (KR) 10-2024-0144636

(51) Int. Cl. G11C 29/12; G11C 29/14; H03L 7/097

(52) U.S. Cl. CPC G11C 29/12015; G11C 29/14; H03L 7/097

(57) ABSTRACT

Disclosed is a method for training a memory device including performing an initialization operation of the memory device, and performing a training operation of the memory device by using a plurality of driving frequencies. The method for training includes setting bits in bit positions in a first control word of a register of a clock driver of the memory device, wherein the bit positions are associated with a control mode and a training mode of a clock signal which is being trained from among the clock signals, performing a training operation to determine a parameter, which is capable of being set, from among a plurality of parameters of the memory device based on the clock signal being trained, and storing the parameter in a second control word of the register of the clock driver.

### CROSS-REFERENCE TO RELATED APPLICATIONS

This application claims priority under 35 U.S.C. § 119 to Korean Patent Application No. 10-2024-0144636 filed on Oct. 22, 2024, in the Korean Intellectual Property Office, the disclosures of which are incorporated by reference herein in their entireties.

### BACKGROUND

Embodiments of the present disclosure described herein relate to a memory module including a memory device, a method for training the memory device, and a method for operating the memory module, and more particularly, relate to a memory module including a clock driver supporting dynamic frequency scaling (DFS), a method for training a memory device, and a method for operating the memory module.

Nowadays, the performance of an electronic device, to which a semiconductor memory device is applied, is improving, and the power consumption of semiconductor memory devices is increasing. A memory system may improve the performance of semiconductor memory devices while reducing power consumption by using dynamic voltage frequency scaling (DVFS).

Moreover, it may be difficult to maintain the integrity of a clock signal in a configuration, in which a plurality of memories are connected, for each channel of a conventional unbuffered dual in-line memory module (UDIMM) and a conventional small outline DIMM (SO-DIMM). Accordingly, in a Joint Electron Device Engineering Council (JEDEC) standard, clocked UDIMM (CUDIMM) and clocked SO-DIMM (CSO-DIMM) standards, which are obtained by adding a clock driver (CKD) to UDIMM and SO-DIMM standards, are being developed.

However, the CUDIMM and CSO-DIMM standards do not support DFS.

### SUMMARY

Embodiments of the present disclosure provide a memory module including a clock driver supporting DFS, a method for training a memory device, and a method for operating the memory module.

According to some embodiments, a method for training a memory device includes performing an initialization operation of the memory device, and performing a training operation of the memory device by using clock signals of a plurality of driving frequencies. The performing of the training operation includes setting bits in bit positions in a first control word of a register of a clock driver of the memory device, wherein the bit positions are associated with a control mode and a training mode of a clock signal which is being trained from among the clock signals, performing a training operation to determine a parameter, which is capable of being set, from among a plurality of parameters of the memory device based on the clock signal being trained, and storing the parameter in a second control word of the register of the clock driver.

The clock signal includes a driving frequency of the plurality of driving frequencies.

According to some embodiments, a memory module includes a plurality of memory devices, and a clock driver device that is configured to receive an input clock signal and configured to transmit at least one output clock signal which is obtained by delaying the input clock signal, to the plurality of memory devices. The clock driver device includes a register that stores at least one control word of the clock driver device, a PLL circuit that receives the input clock signal and outputs an intermediate clock signal, a frequency detection circuit that detects a frequency of the intermediate clock signal, and a clock tree circuit configured to delay the intermediate clock signal based on the at least one control word associated with the frequency that was detected in the register. The register is configured to store a delay value of each of clock signals of a plurality of driving frequencies in different control words.

According to some embodiments, a method for operating a memory module includes receiving an input clock signal from a memory controller, receiving, by a PLL circuit, the input clock signal and outputting an intermediate clock signal, detecting a frequency of the intermediate clock signal, and comparing the detected frequency with reference values stored in advance with respect to each of a plurality of driving frequencies, generating an output clock signal, which is obtained by applying a delay value corresponding to a driving frequency that is identical to the detected frequency.

### BRIEF DESCRIPTION OF THE FIGURES

The above and other objects and features of the present disclosure will become apparent by describing in detail embodiments thereof with reference to the accompanying drawings.

FIG. 1 is a block diagram illustrating a memory system, according to some embodiments of the present disclosure.

FIG. 2 is a drawing illustrating an example of implementing a memory module of FIG. 1.

FIG. 3 is a block diagram illustrating a memory device, according to some embodiments of the present disclosure.

FIG. 4 is a drawing showing a bank array, according to some embodiments of the present disclosure.

FIG. 5 is a flowchart illustrating an operating method of a memory system, according to some embodiments of the present disclosure.

FIG. 6 is a block diagram showing a clock driver, according to some embodiments of the present disclosure.

FIG. 7 is a flowchart for describing an initialization operation of a clock driver, according to some embodiments of the present disclosure.

FIG. 8 is a diagram showing a configuration of a third control word, according to some embodiments of the present disclosure.

FIG. 9 is a flowchart showing a method, in which a memory system trains a memory device, according to some embodiments of the present disclosure.

FIG. 10 is a diagram showing a configuration of a first control word, according to some embodiments of the present disclosure.

FIG. 11 is a diagram showing a configuration of control words, according to some embodiments of the present disclosure.

FIG. 12 is a flowchart showing an operating method of a memory module, according to some embodiments of the present disclosure.

FIG. 13 is a block diagram showing a configuration of a frequency detector, according to some embodiments of the present disclosure.

### DETAILED DESCRIPTION

Hereinafter, embodiments of the present disclosure may be described in detail and clearly to such an extent that an ordinary one in the art easily implements the present disclosure. Herein, the terms indicating order, such as first, second, etc., are used to distinguish elements having the same/similar functions, and the ordinal numbers may be interchanged according to the order in which the terms are mentioned. To clarify the present disclosure, parts that are not connected with the description will be omitted, and the same elements or equivalents are referred to by the same reference numerals throughout the specification.

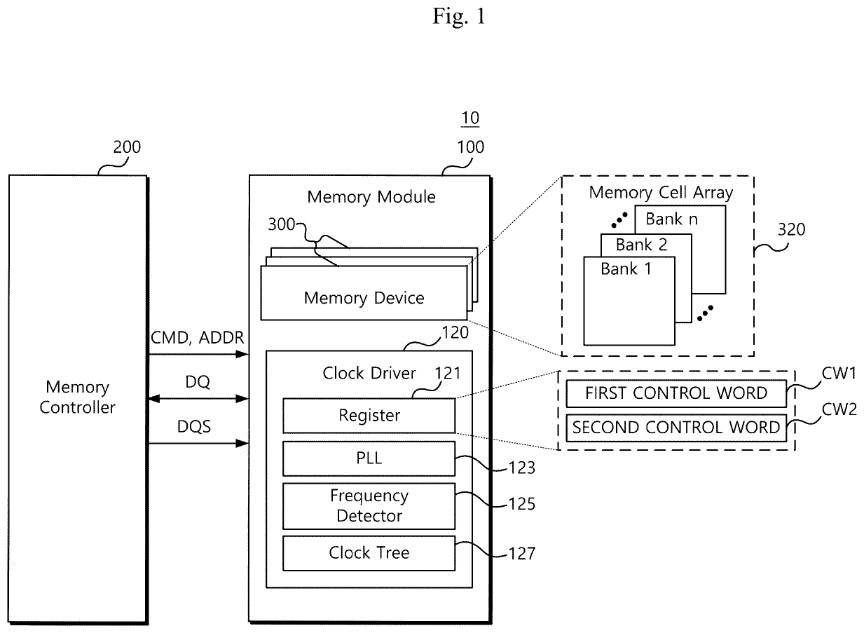

FIG. 1 is a block diagram illustrating a memory system, according to some embodiments of the present disclosure.

When a frequency of a clock signal received from a memory controller 200 is changed, a memory module 100 according to some embodiments of the present disclosure may generate an output clock signal, to which a parameter suitable for the changed frequency is applied. To the end, a memory system 10 may train a memory device 300 with respect to a clock signal of each of a plurality of different driving frequencies.

In this case, the memory system 10 according to the embodiments of the present disclosure may configure control words stored in a register 121 of a clock driver 120 so as to be suitable for a plurality of driving frequency environments.

In more detail with reference to FIG. 1, the memory system 10 may include the memory controller 200 and the memory device 300.

The memory controller 200 may control the memory device 300. For example, the memory controller 200 may control the memory device 300 at the request of a processor supporting various applications, such as a server application, a personal computer (PC) application, and a mobile application. For example, the memory controller 200 may be included in a host including the processor and may control the memory device 300 at the request of the processor.

The memory controller 200 may transmit a command CMD and/or an address ADDR to the memory device 300 to control the memory device 300. Moreover, the memory controller 200 may transmit data DQ to the memory device 300 or may receive the data DQ from the memory device 300.

The memory device 300 may receive the data DQ from the memory controller 200 and may store the data DQ. The memory device 300 may read out the stored data DQ in response to a request of the memory controller 200 and may transmit the stored data DQ to the memory controller 200.

In some embodiments, the memory device 300 may be a memory device including volatile memory cells. For example, the memory device 300 may be various DRAM devices such as a double data rate synchronous dynamic random access memory (DDR SDRAM), DDR2 SDRAM, DDR3 SDRAM, DDR4 SDRAM, DDR5 SDRAM, a low power double data rate (LPDDR) SDRAM, LPDDR2 SDRAM, LPDDR3 SDRAM, LPDDR4 SDRAM, LPDDR4X SDRAM, LPDDR5 SDRAM, a graphics double data rate synchronous graphics random access memory (GDDR SGRAM), GDDR2 SGRAM, GDDR3 SGRAM, GDDR4 SGRAM, GDDR5 SGRAM, GDDR6 SGRAM, etc.

Furthermore, in some embodiments, the memory device 300 may be implemented with a memory device, in which DRAM dies are stacked, such as a high bandwidth memory (HBM), an HBM2, or an HBM3.

Also, in some embodiments, the memory module 100 may be a dual in-line memory module (DIMM) that complies with a Joint Electron Device Engineering Council (JEDEC) standard. For example, the memory module 100 may be a registered DIMM (RDIMM), a load reduced DIMM (LRDIMM), an unbuffered DIMM (UDIMM), a fully buffered DIMM (FB-DIMM), or a small outline DIMM (SO-DIMM). In some embodiments, the memory module 100 may be an unbuffered dual in-line memory module (UDIMM), a small outline DIMM (SO-DIMM), a clocked UDIMM (CUDIMM), and/or a clocked SO-DIMM (CSO-DIMM). However, this is an example, and the memory module 100 may be another memory module, such as a single in-line memory module (SIMM).

The memory module 100 may include the memory device 300 and the clock driver 120.

The memory device 300 may include a memory cell array 320.

The memory cell array 320 includes a plurality of banks Bank 1 to Bank n, each of which includes memory cells for storing data. For convenience of description, it will be assumed in this specification that each bank includes DRAM cells. However, this is an example, and each of the plurality of banks Bank 1 to Bank n may be implemented to include volatile memory cells other than DRAM cells. Furthermore, each of the plurality of banks Bank 1 to Bank n may be implemented to include the same type of memory cells, or may be implemented to include different types of memory cells.

The memory cell array 320 may include a plurality of memory cell rows. Here, the memory cell row may refer to memory cells included in one row.

In some embodiments, the memory cell row may be defined per bank. For example, one bank may be physically and/or electrically connected to a plurality of word lines, and memory cells physically and/or electrically connected to the same word line may form the same memory cell row. In this case, each bank may include a plurality of memory cell rows.

In some embodiments, the memory cell row may be defined per sub-array block. For example, one bank may include a plurality of sub-array blocks, and memory cells, which are physically and/or electrically connected to the same word line, from among the memory cells of each sub-array block may form the same memory cell row. In this case, each sub-array block may include a plurality of memory cell rows.

In some embodiments, a memory cell row may be defined to include memory cells from different banks. For example, two or more banks may share the same word lines, and memory cells in different banks physically and/or electrically connected to the same word line may form the same memory cell row. However, this is an example. According to some embodiments, the memory cell row may be defined in various ways.

The clock driver 120 may clean an input clock signal and may transmit the cleaned output clock signal to the memory device 300. As the clock driver 120 uses a clock tree 127 on the input clock signal, the memory module 100 may operate at a high driving frequency and transfer speed. The clock driver 120 may also be referred to as a “clock buffer driver”.

The clock driver 120 may include the register 121, a phase-locked loop (PLL) 123, a frequency detector 125, and the clock tree 127.

The register 121 may be configured to store control words for supporting device properties of the memory device 300. The register 121 may include a plurality of control words. The control word may also be referred to as a “register control word (RCW)”.

In some embodiments, the plurality of control words may include control words that comply with the JEDEC clock driver (CKD) standard. For example, the plurality of control words may support a DDR5CK01 device of JEDEC.

In some embodiments, each of the plurality of control words may include 8 bits. The device properties of the memory device 300 may be optimized through the control words.

In some embodiments, the control words may be set to a ‘0 ’ state at power-on. In some embodiments, some control words or some bits of some control words may be set to a ‘1’ state at power-on. The control words may be erased at power-off of the memory module 100, not by a DRST_n signal of the memory controller 200. Even when the memory device 300 enters a low power mode or wakes up from a low power state, settings of a control word may not be changed.

The PLL 123 may stabilize the input clock signal by removing jitter from the input clock signal.

The clock tree 127 may include a plurality of delay elements. The clock tree 127 may output at least one clock signal, which is obtained by delaying the input clock signal by a delay value. For example, some control words may store the delay value of the input clock signal. The memory controller 200 may set the delay value of at least one clock signal output by the clock tree 127 in the control word of the register 121.

In some embodiments of the present disclosure, the register 121 may be configured to store a first control word CW1 and a second control word CW2 at a preset register address.

In some embodiments, the first control word CW1 may include one control word in the register 121, and the second control word CW2 may include a plurality of control words in the register 121. The plurality of second control words CW2 are present. For example, the second control words CW2 may be formed as many as the number of driving frequencies capable of being supported by the clock driver 120. Accordingly, addresses, which correspond to the number of driving frequencies capable of being supported by the clock driver 120, among the addresses of the register 121 may be used for the second control words CW2.

In some embodiments, the first control word CW1 may be set to a state that is different depending on the operating mode of the memory module 100. For example, some bits of the first control word CW1 may be used to set a control mode, and other bits of the first control word CW1 may be used to set a training mode.

In some embodiments, the second control words CW2 may store a delay value for delaying each of clock signals of a plurality of driving frequencies. Accordingly, the memory module 100 may operate based on a DFS technique that dynamically changes the driving frequency of a clock signal. When the frequency of the input clock signal changes, the clock driver 120 may identify the delay value, which is suitable for the frequency of the clock signal detected by the frequency detector 125, by using the second control words CW2. The clock tree 127 may delay a clock signal, of which the frequency is changed, by the suitable delay value based on the second control word CW2. As a result, even when the frequency of the input clock signal changes, the clock driver 120 may output a stable and clean clock signal. The memory device 300 may operate stably even though the frequency of the clock signal changes.

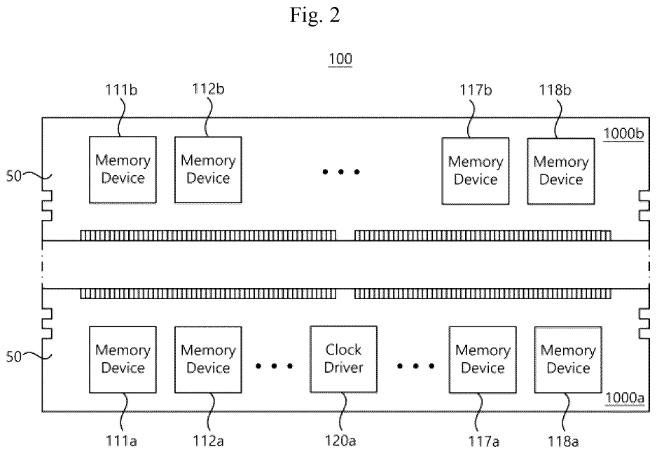

FIG. 2 is a drawing illustrating an example of implementing the memory module 100 of FIG. 1.

The memory module 100 may include a circuit board 50, first memory devices 111a, 112a, . . . 117a, and 118a mounted on first surface 1000a of the circuit board 50, and second memory devices 111b, 112b, . . . 117b, and 118b mounted on second surface 1000b, opposite first surface 1000a, of the circuit board 50.

FIG. 2 illustrates that eight memory devices are mounted on each of the first surface 1000a and the second surface 1000b of the circuit board 50, but in an actual implementation, fewer or more memory devices may be mounted. For example, the number or arrangement of the first memory devices 111a, 112a, . . . 117a, and 118a and the second memory devices 111b, 112b, . . . 117b, and 118b may vary depending on standards or specifications of the memory module 100.

The first memory devices 111a, 112a, . . . , 117a, and 118a and the second memory devices 111b, 112b, . . . , 117b, and 118b may be mounted respectively opposite to each other on the circuit board 50. For example, the first memory device 111a and the second memory device 111b may be mounted opposite to each other on the circuit board 50. Moreover, the first memory device 112a and the second memory device 112b may be mounted opposite to each other on the circuit board 50. In this manner, the remaining first memory devices and the remaining second memory devices may be mounted respectively opposite to each other on the circuit board 50.

The memory module 100 may include a clock driver. For example, the memory module 100 may include a clock driver 120a mounted on the first surface 1000a of the circuit board 50.

The first memory devices 111a, 112a, . . . , 117a, and 118a and the second memory devices 111b, 112b, . . . , 117b, and 118b are mounted respectively opposite to each other on the circuit board 50, and the clock driver 120a may be mounted on the first surface 1000a of the circuit board 50. In this case, the clock driver 120a may transmit a clock signal to the first memory devices 111a, 112a, . . . , 117a, and 118a and to the second memory devices 111b, 112b, . . . , 117b, and 118b.

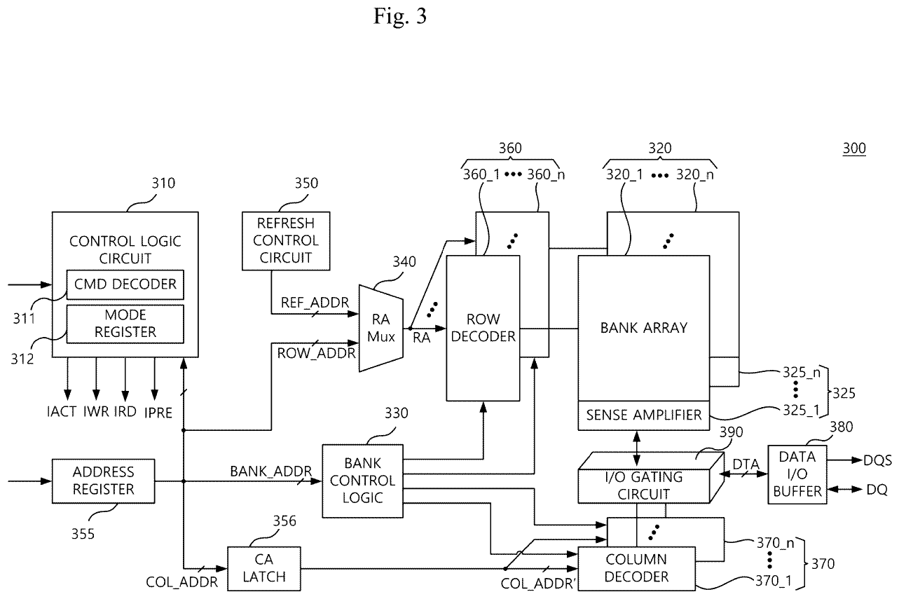

FIG. 3 is a block diagram illustrating the memory device 300, according to some embodiments of the present disclosure. The memory device 300 of FIG. 3 may correspond to the memory device 300 of FIG. 1.

Referring to FIG. 3, the memory device 300 may include a control logic circuit 310, an address register 355, a bank control logic 330, a refresh control circuit 350, a row address multiplexer 340, a column address latch 356, a row decoder 360, a column decoder 370, the memory cell array 320, a sense amplification unit 325, an input/output gating circuit 390, and a data input/output buffer 380.

The memory cell array 320 may include a plurality of bank arrays 320_1 to 320_n. Each of the plurality of bank arrays 320_1 to 320_n may include a plurality of memory cells. For example, each of the plurality of memory cells may be formed at an intersection of a corresponding word line and a corresponding bit line.

The row decoder 360 may include a plurality of sub-row decoders 360_1 to 360_n. Each of the plurality of sub-row decoders 360_1 to 360_n may be physically and/or electrically connected to a corresponding bank array among the plurality of bank arrays 320_1 to 320_n.

The sense amplification unit 325 may include a plurality of sense amplifiers 325_1 to 325_n. Each of the plurality of sense amplifiers 325_1 to 325_n may be physically and/or electrically connected to a corresponding bank array among the plurality of bank arrays 320_1 to 320_n.

The column decoder 370 may include a plurality of sub-column decoders 370_1 to 370_n. Each of the plurality of sub-column decoders 370_1 to 370_n may be physically and/or electrically connected to a corresponding bank array among the plurality of bank arrays 320_1 to 320_n through a corresponding sense amplifier.

The plurality of bank arrays 320_1 to 320_n, the plurality of sense amplifiers 325_1 to 325_n, the plurality of column decoders 370_1 to 370_n, and the plurality of row decoders 360_1 to 360_n may be part of a plurality of banks, respectively. For example, the first bank array 320_1, the first sense amplifier 325_1, the first column decoder 370_1, and the first row decoder 360_1 may be part of a first bank.

The address register 355 may receive the address ADDR including a bank address BANK_ADDR, a row address ROW_ADDR, and a column address COL_ADDR from the memory controller 200. The address register 355 may provide the received bank address BANK_ADDR to the bank control logic 330, may provide the received row address ROW_ADDR to the row address multiplexer 340, and may provide the received column address COL_ADDR to the column address latch 356.

The bank control logic 330 may generate bank control signals in response to the bank address BANK_ADDR. For example, in response to the bank control signals, a row decoder corresponding to the bank address BANK_ADDR among the plurality of row decoders 360_1 to 360_n may be activated. In response to the bank control signals, a column decoder corresponding to the bank address BANK_ADDR among the plurality of column decoders 370_1 to 370_n may be activated.

The row address multiplexer 340 may receive the row address ROW_ADDR from the address register 355 and may receive a refresh row address REF_ADDR from the refresh control circuit 350. The row address multiplexer 340 may selectively output the row address ROW_ADDR or the refresh row address REF_ADDR as a row address RA. The row address RA output from the row address multiplexer 340 may be applied to each of the plurality of row decoders 360_1 to 360_n.

In a normal refresh mode, the refresh control circuit 350 may sequentially increase or decrease the refresh row address REF_ADDR in response to refresh signals from the control logic circuit 310.

A row decoder, which is selected by the bank control logic 330, from among the plurality of row decoders 360_1 to 360_n may activate a word line corresponding to the row address RA output from the row address multiplexer 340. For example, the selected row decoder may apply a word line driving voltage to a word line corresponding to a row address.

The column address latch 356 may receive the column address COL_ADDR from the address register 355 and may temporarily store the received column address COL_ADDR.

Moreover, for example, in a burst mode, the column address latch 356 may gradually increase the received column address COL_ADDR. The column address latch 356 may apply a column address COL_ADDR′, which is temporarily stored or gradually increased, to the plurality of column decoders 370_1 to 370_n.

A column decoder, which is activated by the bank control logic 330, from among the plurality of column decoders 370_1 to 370_n may activate a sense amplifier corresponding to the bank address BANK_ADDR and the column address COL_ADDR through the input/output gating circuit 390.

The input/output gating circuit 390 may include circuits that gate input/output data. Moreover, the input/output gating circuit 390 may include data latches for storing codewords output from the plurality of bank arrays 320_1 to 320_n, and write drivers for writing data to the plurality of bank arrays 320_1 to 320_n.

In some embodiments, during a read operation, data DTA read from the selected bank array among the plurality of bank arrays 320_1 to 320_n may be detected by a sense amplifier corresponding to the selected bank array and may be stored in data latches of the input/output gating circuit 390. Moreover, the data DTA stored in the data latches may be provided to the data input/output buffer 380. The data input/output buffer 380 may generate a data signal DQ based on the data DTA, and may provide the data signal DQ to the memory controller 200 together with a data strobe signal DQS.

In some embodiments, during a write operation, the data DTA to be written to the selected bank array among the plurality of bank arrays 320_1 to 320_n may be received as the data signal DQ by the data input/output buffer 380. The input/output gating circuit 390 may write the data DTA to the selected bank array.

The control logic circuit 310 may control the operation of the memory device 300. For example, the control logic circuit 310 may generate control signals to cause the memory device 300 to perform a write operation, a read operation, and a refresh operation. The control logic circuit 310 may include a command decoder 311 for decoding the command CMD received from the memory controller 200 and a mode register set (MRS) 312 for setting the operating mode of the memory device 300.

The command decoder 311 may generate internal command signals, such as an internal active signal IACT, an internal precharge signal IPRE, an internal read signal IRD, and an internal write signal IWR by decoding the command CMD. Moreover, the command decoder 311 may generate control signals corresponding to the command CMD by decoding a chip select signal and a command/address signal.

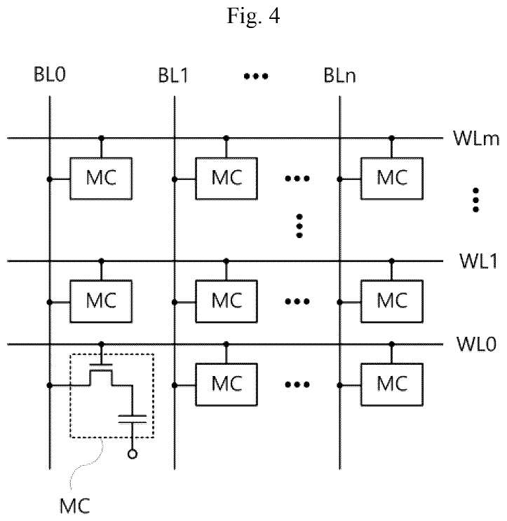

FIG. 4 is a drawing showing an example of a bank array, according to some embodiments of the present disclosure. For example, a bank array of FIG. 4 may correspond to the first bank array 320_1 of FIG. 3.

Referring to FIGS. 3 and 4, the first bank array 320_1 may include a plurality of word lines WL0 to WLm, a plurality of bit lines BL0 to BLn, and a plurality of memory cells MCs positioned at intersections between the word lines WL0 to WLm and the bit lines BL0 to BLn.

In some embodiments, each memory cell MC may be a DRAM cell. For example, each of the memory cells MCs may include a cell transistor physically and/or electrically connected to a word line and a bit line, and a cell capacitor physically and/or electrically connected to the cell transistor.

Word lines extending in a row direction may be referred to as “rows of the first bank array 320_1”. Bit lines extending in a column direction may be referred to as “columns of the first bank array 320_1”.

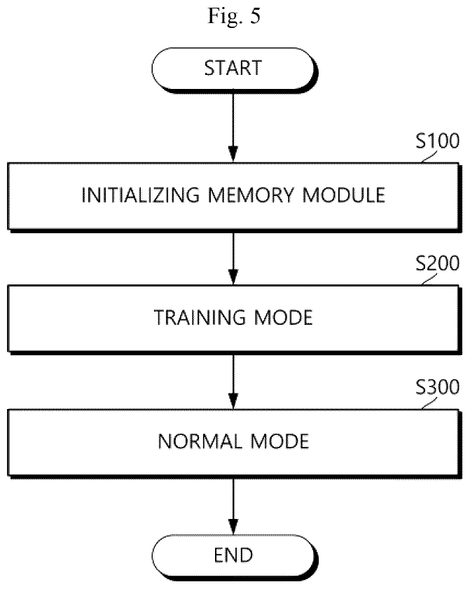

FIG. 5 is a flowchart illustrating an operating method of a memory system, according to some embodiments of the present disclosure. An operating method of FIG. 5 may be performed by the memory system 10 of FIG. 1. The operating method of the memory system 10 is described with reference to FIGS. 1 and 5.

In operation S100, the memory system 10 may perform an initialization operation of the memory module 100. The initialization operation of the memory module 100 may include an initialization operation of the memory device 300 and an initialization operation of the clock driver 120.

In some embodiments, the initialization operation of the memory device 300 may include an operation of applying a power supply voltage to the memory device 300 upon power-on of the memory device 300, and an operation of transmitting signals necessary for initialization until a normal operation begins. For example, the memory controller 200 may transmit a reset signal to the memory device 300 after the power supply voltage is stabilized and then a predetermined period of time expires. After the reset signal is maintained at a logic low level, the reset signal may be toggled. The reset signal may be configured as a signal for initializing the memory device 300 to be in a reset state for proper operation.

In some embodiments, after a reset operation of the memory device 300, the commands CMD of FIG. 1 issued to the memory device 300 according to a power-on sequence of the memory system 10 may be sequentially stored in the command decoder 311 of FIG. 3. The command decoder 311 may sequentially store commands required for initialization of the memory device 300 depending on a predetermined initialization sequence and may output the corresponding command in the stored order.

In some embodiments, during the initialization operation of the clock driver 120, the memory controller 200 may determine whether the clock driver 120 supports DFS. Moreover, in some embodiments, when the clock driver 120 supports the DFS, the memory controller 200 may determine the number of driving frequencies supported by the clock driver 120.

In operation S200, the memory system 10 may perform a training operation of the memory module 100 on which the initialization operation is completed.

The training operations may include an operation of training a memory device thus conventionally known.

In some embodiments, during the training operation, a test operation may be performed on the memory module 100 as part of a power-on self-test (POST). A command to the memory device 300 may be issued during the test operation. For example, the training operation may include, but are not limited to, interface tuning tasks such as clock training, write/read leveling, write/read de-skew, and write/read centering. Furthermore, an operation other than the above-mentioned operation may be performed, or the above-mentioned operation may not be performed. During the test operation, a cell array of the memory device 300, such as the illustration in FIG. 4, may also be tested. The cell array may be tested through data write/read operations after the interface tuning task is completed.

In some embodiments, the training operation may include an operation of determining a delay value for compensating for skew between a clock signal and a data strobe signal. The delay value may be determined for each channel of the memory device 300, or each of the plurality of memory devices 300.

According to some embodiments of the present disclosure, when the clock driver 120 supports the DFS, the memory system 10 may determine delay values for compensating for skew between the data strobe signal and each of clock signals of a plurality of supported driving frequencies, and may store the determined delay values in the second control word CW2.

In operation S300, the memory system 10 may operate the memory module 100, on which the training operation is completed, in a normal mode. For example, at the request of the operating system of a host, the memory controller 200 may read out data from the memory device 300 or may write data to the memory device 300.

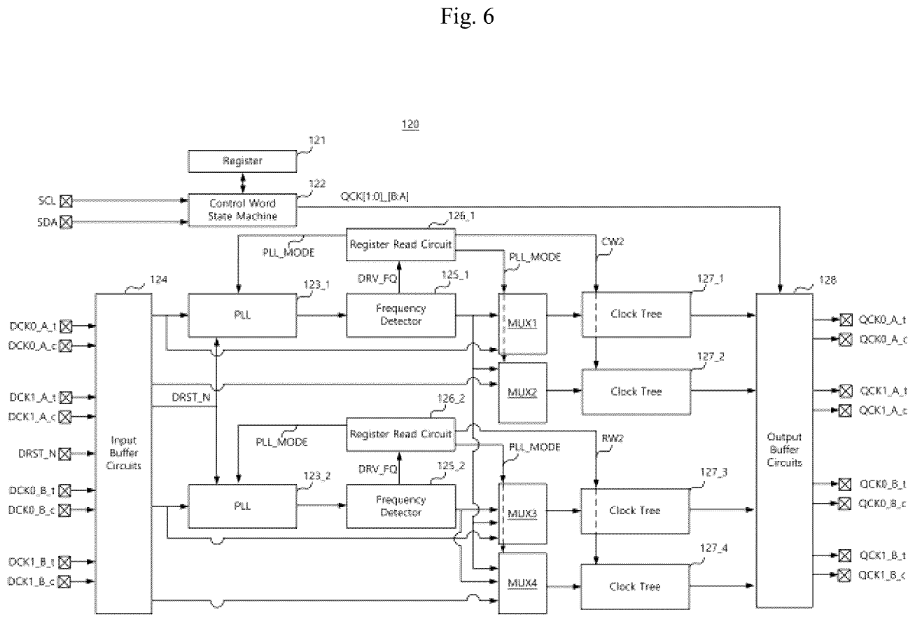

FIG. 6 is a block diagram showing a clock driver, according to some embodiments of the present disclosure. The clock driver 120 of FIG. 6 may correspond to the clock driver 120 of FIG. 1. some embodiments of the clock driver 120 is described with reference to FIGS. 1 and 6.

In some embodiments, referring to FIG. 6, the clock driver 120 may include the register 121, a control word state machine 122, PLLs 123_1 and 123_2, input buffer circuits 124, frequency detectors 125_1 and 125_2, multiplexers MUX1 to MUX4, clock trees 127_1, 127_2, 127_3, 127_4, and output buffer circuits 128.

The register 121 may include control words. Each of the control words may be set to various configuration values for controlling the memory device 300 to be suitable for the initialization and/or operating characteristics of the memory device 300.

The control word state machine 122 may provide a method for accessing the register 121. The control word state machine 122 may read out the control words from the register 121 or may set at least one control word among the control words. The reading of a control word may include reading bit values set in the control word. The writing of a control word may include setting at least one bit position of the control word to a specific bit value.

The control word state machine 122 may provide the memory controller 200 with a method for accessing the register 121 through sideband bus channel commands of a JEDEC standard received from the memory controller 200. For example, through the sideband bus channel command, the memory controller 200 may read out at least one control word stored in the register 121 or may set a bit of at least one control word. The sideband bus channel command may be received through an SDA pin of the clock driver 120 that is specified by JEDEC. The sideband bus channel command may be received based on Inter-Integrated Circuit (I²C) protocol or Improved Inter-Integrated Circuit (I3C) protocol. The control word state machine 122 may operate based on a sideband clock signal (SCL).

The input buffer circuits 124 may be composed of or include a plurality of input buffer circuits. The input buffer circuit may be a differential buffering circuit that may be configured to receive a differential input clock signal pair and configured to output a comparison signal. The input buffer circuits 124 may be configured to receive four differential input clock signal pairs. For example, referring to FIG. 6, the input buffer circuits 124 may be configured to receive a first differential input clock signal pair DCK0_A_t and DCK0_A_c, a second differential input clock signal pair DCK1_A_t and DCK1_A_c, a third differential input clock signal pair DCK0_B_t and DCK0_B_c, and a fourth differential input clock signal pair DCK1_B_t and DCK1_B_c, and to output comparison signals respectively. Some of the comparison signals may be transmitted to the PLLs 123_1 and 123_2. The comparison signals may be transmitted to the first multiplexer MUX1, the second multiplexer MUX2, the third multiplexer MUX3, and the fourth multiplexer MUX4, respectively. Signals output by the PLLs 123_1 and 123_2 may be referred to as “intermediate clock signals”.

One of the input buffer circuits that makes up the input buffer circuits 124 may receive an enable signal DRST_n and may transmit the enable signal DRST_n to the PLLs 123_1 and 123_2.

Each of the PLLs 123_1 and 123_2 may transmit an intermediate clock signal to the first multiplexer MUX1 and the third multiplexer MUX3 through the frequency detectors 125_1 and 125_2 based on a mode signal PLL_MODE.

The mode signal PLL_MODE may be a signal specified in JEDEC so as to output four differential output clock signal pairs such as a first differential output clock signal pair QCK0_A_t and QCK0_A_c, a second differential output clock signal pair QCK1_A_t and QCK1_A_c, a third differential output clock signal pair QCK0_B_t and QCK0_B_c, and a fourth differential output clock signal pair QCK1_B_t and QCK1_B_c. The mode signal PLL_MODE may be a single mode signal for operating one of the PLLs 123_1 and 123_2, or a dual mode signal for operating both the PLLs 123_1 and 123_2. In some embodiments, the mode signal PLL_MODE may be a bypass mode signal for bypassing the PLLs 123_1 and 123_2. The mode signal PLL_MODE may be read out from the register 121 through register read circuits 126_1 and 126_2. For example, the register read circuits 126_1 and 126_2 may read out the mode signal PLL_MODE from a predetermined control word by directly accessing the register 121, or may read out the mode signal PLL_MODE through the control word state machine 122.

The multiplexer MUX1 may select one of input signals based on the mode signal PLL_MODE and may transmit the selected one of the input signals to the clock tree 127_1; the multiplexer MUX2 may select one of input signals based on the mode signal PLL_MODE and may transmit the selected one of the input signals to the clock tree 127_2; the multiplexer MUX3 may select one of input signals based on the mode signal PLL_MODE and may transmit the selected one of the input signals to the clock tree 127_3; and, the multiplexer MUX4 may select one of input signals based on the mode signal PLL_MODE and may transmit the selected one of the input signals to the clock tree 127_4.

Each of the clock trees 127_1, 127_2, 127_3, 127_4 may generate an output signal obtained by delaying an input signal and may transmit the output signal to the output buffer circuits 128.

The output buffer circuits 128 may be composed of or include a plurality of output buffer circuits. The output buffer circuit may be configured to output a differential output clock signal pair based on the input signal.

For example, referring to FIG. 6, the output buffer circuits 128 may be configured to output four differential output clock signal pairs such as the first differential output clock signal pair QCK0_A_t and QCK0_A_c, the second differential output clock signal pair QCK1_A_t and QCK1_A_c, the third differential output clock signal pair QCK0_B_t and QCK0_B_c, and the fourth differential output clock signal pair QCK1_B_t and QCK1_B_c.

The register 121 according to some embodiments of the present disclosure may be configured to store the first control word CW1 and the second control word CW2. In some embodiments, the register 121 may be configured to further store a third control word CW3.

The first control word CW1 may store information capable of distinguishing between a control mode and a training mode of each of clock signals of a plurality of driving frequencies. That is, the first control word CW1 may include activation information of the control mode and training mode of each of clock signals of a plurality of different driving frequencies.

When the clock driver 120 supports the DFS, the second control word CW2 may store delay values for delaying clock signals of a plurality of driving frequencies thus supported. For example, when the clock driver 120 supports DFS, the memory system 10 may determine delay values for compensating for skew between a data strobe signal and a clock signal of each of a plurality of driving frequencies, which are supported by the clock driver 120, during the training operation of the memory device 300. The memory system 10 may store the determined delay values in the second control word CW2.

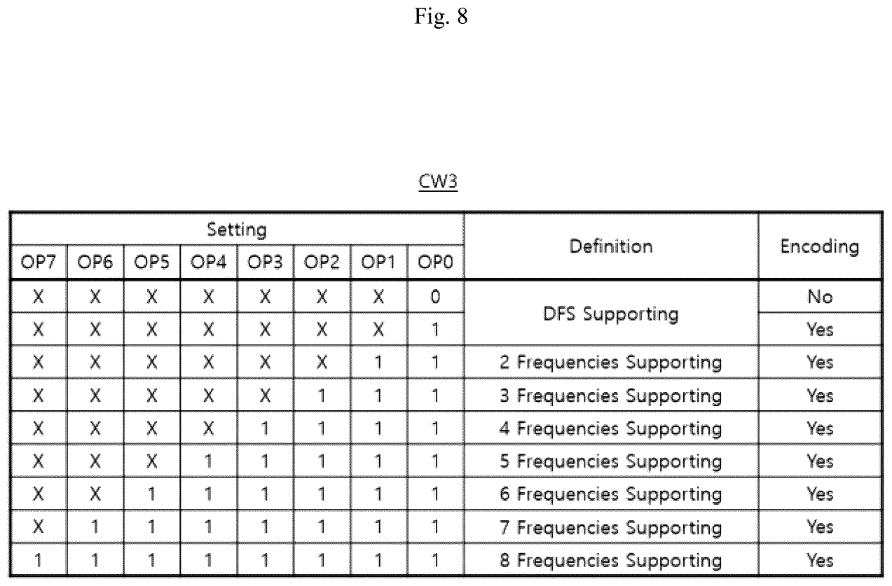

The third control word CW3 may be the third control word CW3 of some embodiments given with reference to FIG. 8. The third control word CW3 may be set depending on the number of supported driving frequencies, and whether the clock driver 120 supports DFS. At least some bit positions of the third control word CW3 may be set in advance depending on the configuration of the clock driver 120. The third control word CW3 may be set to a read-only attribute.

The clock driver 120 may include the frequency detectors 125_1 and 125_2. In a normal mode, the frequency detectors 125_1 and 125_2 may detect frequencies of input signals transmitted from the PLLs 123_1 and 123_2, respectively.

Each of the frequency detectors 125_1 and 125_2 may detect the frequency of a clock signal being trained during a training operation of the memory module 100 and may store the detected frequency in a storage device. For example, each of the frequency detectors 125_1 and 125_2 may convert the detected frequency into a voltage value and may store the converted voltage value in a capacitor.

During a normal operation of the memory module 100, each of the frequency detectors 125_1 and 125_2 may detect the frequency of the clock signal received from the memory controller 200. Each of the frequency detectors 125_1 and 125_2 may compare a voltage value, which is obtained by converting the detected frequency into a voltage, with a voltage value stored in a storage device. As the comparison result, the frequency detectors 125_1 and 125_2 may output a frequency DRV_FQ corresponding to the matching voltage value. The register read circuits 126_1 and 126_2 may read out the second control word CW2 corresponding to the frequency DRV_FQ from the register 121.

For example, when the frequency DRV_FQ corresponding to the matching voltage value is a first frequency, the frequency detectors 125_1 and 125_2 may read out the second control word CW2 corresponding to the first frequency among the plurality of second control words CW2.

The clock trees 127_1, 127_2, 127_3, 127_4 may receive the second control word CW2 corresponding to the first frequency, and may delay a clock signal based on a delay value obtained by delaying a clock signal of the first frequency.

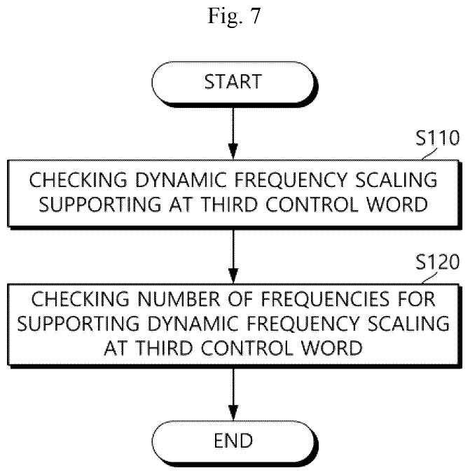

FIG. 7 is a flowchart for describing an initialization operation of a clock driver, according to some embodiments of the present disclosure. A method of FIG. 7 may be performed on the clock driver 120 by the memory system 10 of FIG. 1. The method of FIG. 7 may be performed during the initialization operation S100 in the operating method of the memory system 10 described with reference to FIG. 5.

An operation in which the memory system 10 initializes the clock driver 120 is described with reference to FIGS. 1 and 7.

Referring to FIG. 7, in operation S110, the memory system 10 may determine whether the clock driver 120 supports DFS.

For example, the memory controller 200 may determine whether a plurality of driving frequencies of a clock signal transmitted to the clock driver 120 are supported. The memory controller 200 may determine whether the clock driver 120 supports DFS, by checking the control word stored at the predetermined address of the register 121. For example, the memory controller 200 may check a third control word stored in the register 121.

In some embodiments, the third control word may be the third control word CW3 of FIG. 8 described below. For example, the memory controller 200 may determine whether the clock driver 120 supports DFS, by checking the bit setting of a specific bit position of the third control word CW3. A flag indicating whether DFS is supported may be set in a specific bit position of the third control word CW3.

When the clock driver 120 supports the DFS, in operation S120, the memory controller 200 may determine the number of driving frequencies supported by the clock driver 120. The memory controller 200 may determine the number of driving frequencies of the clock signal supported by the clock driver 120. For example, the number of driving frequencies supported by the clock driver 120 may be checked by checking bit settings of specific bit positions of the third control word CW3 of FIG. 8.

According to some embodiments of the present disclosure, a method, in which the memory system 10 determines whether DFS of the clock driver 120 is supported, is not limited to the method using the third control word CW3 of FIG. 8. For example, the number of supported driving frequencies and whether the clock driver 120 supports DFS may be set in various ways in an inactive memory area other than the register 121 of FIG. 1.

FIG. 8 is a diagram showing a configuration of the third control word CW3, according to some embodiments of the present disclosure.

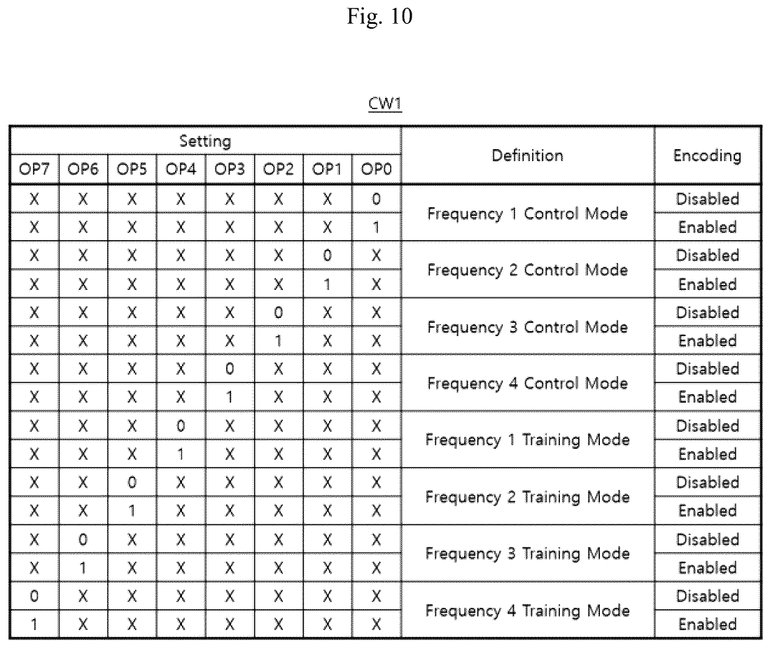

In some embodiments, the third control word CW3 may be identical to the third control word CW3 described with reference to FIG. 10 below. That is, the third control word CW3 of FIG. 8 may be stored as one control word at a predetermined address of the register of FIG. 10.

The method of setting the third control word CW3 is described with reference to FIG. 8.

In some embodiments, the third control word CW3 may be set to have a read-only property.

In some embodiments, the third control word CW3 may be set depending on the number of supported driving frequencies, and whether the clock driver 120 supports DFS.

In some embodiments, the third control word CW3 may be composed of or include one control word stored in the register 121 of FIG. 1 and may be composed of or include 8 bits. For example, referring to FIG. 8, the third control word CW3 may include 8 bit positions OP0 to OP7.

In some embodiments, the first bit position OP0 of the third control word CW3 may be preset to a flag indicating whether the clock driver 120 supports DFS.

For example, referring to FIG. 8, when the first bit position OP0 of the third control word CW3 is set to a state of ‘0’, the memory system 10 may determine that the clock driver 120 does not support DFS. In this case, a delay value for compensating for the skew between a data strobe and a clock signal of one frequency may be stored in the second control word CW2 of the register 121 described with reference to FIG. 10 below.

In some embodiments, when the first bit position OP0 of the third control word CW3 is set to a state of ‘1’, the memory system 10 may check bit settings of the second to eighth bit positions OP1 to OP7 of the third control word CW3 and may check the maximum number of driving frequencies supported by the clock driver 120.

For example, when bit settings of the second to eighth bit positions OP1 to OP7 of the third control word CW3 are ‘111’, the memory system 10 may check that the clock driver 120 supports up to three driving frequencies. In this case, delay values for compensating for skews between the data strobe and clock signals of three frequencies may be respectively stored in the second control word CW2 of the register 121 described with reference to FIG. 10 below. In some embodiments, delay values for compensating for skews between the data strobe and clock signals of three frequencies may be stored in the second control word CW2 of the register 121 described with reference to FIG. 10. Here in this non-limiting example, the number of delay values is less than three.

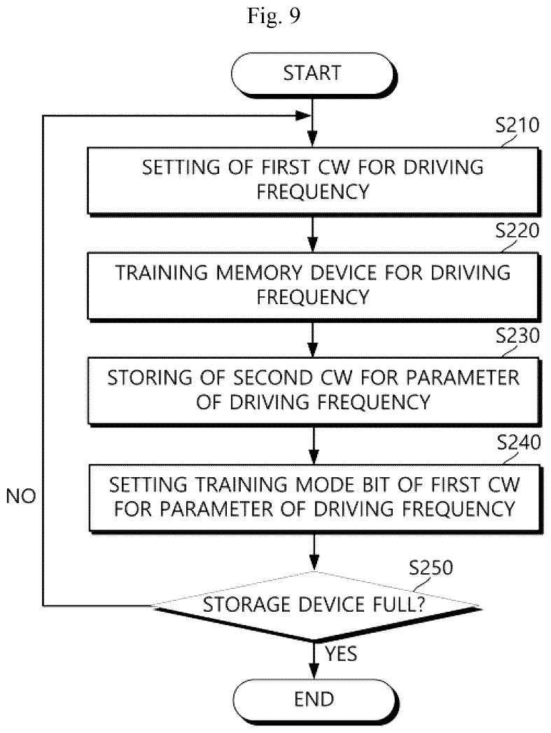

FIG. 9 is a flowchart showing a method, in which a memory system trains a memory device, according to some embodiments of the present disclosure. A training method of FIG. 9 may be performed by the memory system 10 of FIG. 1. A method in which the memory system 10 trains the memory device 300 is described with reference to FIGS. 1 and 9.

In some embodiments, the method of training the memory device 300 of FIG. 8 may be performed as part of operation S200 of FIG. 5.

In operation S210, the clock driver 120 may receive a first clock signal having a first driving frequency.

The memory system 10 may set values of bits in bit positions corresponding to a control mode and a training mode of the clock signal of the first driving frequency to “enable” in the first control word CW1 of the register 121. The memory system 10 may activate both the control mode and the training mode of the clock signal of the first driving frequency.

In operation S220, the memory system 10 may perform a training operation of determining at least one settable parameter among a plurality of parameters of the memory device 300 based on the first clock signal of the first driving frequency being trained. The at least one parameter may be determined through interface tuning tasks such as clock training, write/read leveling, write/read de-skew, and write/read centering.

For example, the parameter may be a delay value for compensating for the skew between a data strobe and the first clock signal of the first driving frequency.

In operation S230, the memory system 10 may store the determined parameter in the second control word CW2 of the register 121. For example, the delay value for compensating for the skew between the data strobe and the first clock signal of the first driving frequency may be stored in the second control word CW2.

The frequency detectors 125_1 and 125_2 of FIG. 6 may detect the first driving frequency from the first clock signal of the first driving frequency and may store a value of the detected first driving frequency in a storage device. For example, the frequency detectors 125_1 and 125_2 may convert the value of the first driving frequency into a voltage value and then may store the voltage value in the storage device.

When the training operation of the memory device 300 based on the first clock signal of the first driving frequency is completed, in operation S240, the memory system 10 may set a bit value of a bit position corresponding to the training mode of the first driving frequency to “disable” in the first control word CW1 of the register 121. The memory system 10 may deactivate the training mode of the clock signal of the first driving frequency.

When the storage device is full of frequency values, in operation S250, the memory system 10 may terminate the training of the clock driver 120 for supporting DFS. When the storage device is not full of frequency values, the memory system 10 may repeat operation S210, operation S220, operation S230, and operation S240 on a second clock signal having a second driving frequency for supporting DFS.

In some embodiments, the memory system 10 may repeat operation S210, operation S220, operation S230, and operation S240 on each of a plurality of clock signals having different frequencies for DFS.

In some embodiments, the memory system 10 may train the memory device 300 based on a clock signal having a lower frequency from among a plurality of clock signals having different frequencies for DFS. For example, when the first driving frequency is lower than the second driving frequency, the memory device 300 may be trained first by using the first clock signal having the first driving frequency.

FIG. 10 is a diagram showing a configuration of the first control word CW1, according to some embodiments of the present disclosure. The first control word CW1 of FIG. 10 may correspond to the first control word CW1 of FIG. 1.

The first control word CW1 may store information capable of distinguishing between a control mode of a clock signal of a driving frequency and a training mode of the driving frequency.

For example, the first control word CW1 may be composed of or include a plurality of bit positions, and each bit position may be set to a flag capable of identifying one of the control mode and training mode of the driving frequency.

For example, referring to FIG. 10, the first control word CW1 of FIG. 10 may store information capable of distinguishing between the control mode and the training mode of each of clock signals of four different frequencies.

In FIG. 10, the first bit position OP0 of the first control word CW1 may be set to a bit value indicating whether the control mode of the clock signal of the first frequency is enabled or disabled. When the first bit position OP0 is set to ‘1’, the control mode of the clock signal of the first frequency may be set to “enable”. Likewise, the second bit position OP1, the third bit position OP2, and the fourth bit position OP3 may be set to a bit value indicating whether the control mode of the clock signal of the second frequency, the clock signal of the third frequency, and the clock signal of the fourth frequency is enabled or disabled, respectively.

As in the above description, the fifth bit position OP4, the sixth bit position OP5, the seventh bit position OP6, and the eighth bit position OP7 may be set to a bit value indicating whether the training mode of the clock signal of the first frequency, the clock signal of the second frequency, the clock signal of the third frequency, and the clock signal of the fourth frequency is enabled or disabled, respectively.

In some embodiments, clock signals of four different frequencies for supporting DFS may be used. In this case, the memory system 10 may train the memory device 300 by using clock signals of four different frequencies.

For example, when training the clock signals of the four different frequencies, the memory system 10 may set the fifth bit position OP4, the sixth bit position OP5, the seventh bit position OP6, and the eighth bit position OP7 of the first control word CW1 to “enable,” and may set the corresponding bit position to “disable”again when the training mode is terminated.

For example, a training operation may be performed by sequentially using the clock signal of the first frequency, the clock signal of the second frequency, the clock signal of the third frequency, and the clock signal of the fourth frequency. In this case, the memory system 10 may set the fifth bit position OP4 of the first control word CW1 corresponding to the training mode of the clock signal of the first frequency to “enable”, and then may perform the training operation by using the clock signal of the first frequency. After the training operation is completed by using the clock signal of the first frequency, the memory system 10 may set the fifth bit position OP4 of the first control word CW1 to “disable”, and then may perform the training operations by using the clock signals of the remaining frequencies in the same manner as the clock signal of the first frequency.

In some embodiments, the memory controller 200 may support clock signals of fewer or more frequencies than the number supported by the first control word CW1. For example, when the memory controller 200 supports DFS using clock signals of three different frequencies, the fourth bit position OP3 corresponding to the control mode of the clock signal of the fourth frequency of the first control word CW1 in FIG. 10 may be set to “disabled”.

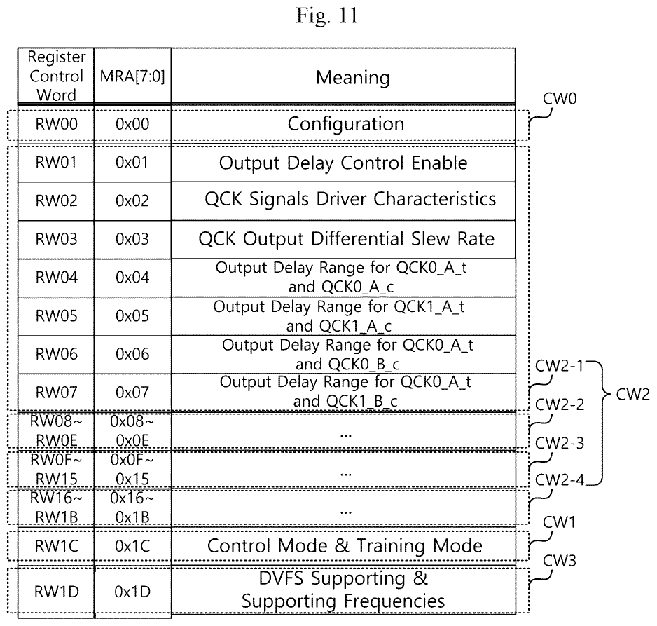

FIG. 11 is a diagram showing a configuration of control words, according to some embodiments of the present disclosure. The control words of FIG. 11 may be configured to be stored in the register 121 of FIGS. 1 and 6. The control words are described with reference to FIGS. 1, 6, and 11. Detailed descriptions of parts identical or similar to those described with reference to FIGS. 1 to 10 will be omitted.

Referring to FIG. 11, the register 121 of FIG. 1 may be configured to store a 0th control word CW0, the first control word CW1, the second control word CW2, and the third control word CW3. Besides, the register 121 may be configured to store control words specified by JEDEC to control a clock driver (CKD) of CUDIMM or CSO-DIMM.

FIG. 11 illustrates control words RW00 to RW1F. The RWxx format in FIG. 11 indicates an index that identifies each control word, and “xx”indicates a hexadecimal number.

FIG. 11 shows a mode register address MRA[7:0], in which control words are stored, and the meaning of each of the control words. Each control word may have an 8-bit configuration.

For example, the 0th control word RW00 may be stored from address 0x00 to address 0x07 of the register 121. The 0th control word RW00 may include the overall settings of the clock driver 120. For example, the mode signal PLL_MODE described in some embodiments with reference to FIG. 6 may be stored in [1:0] bit positions of the 0th control word RW00.

There may be the plurality of second control words CW2 according to some embodiments of the present disclosure. The second control word CW2 may be stored in the register 121 for each of the clock signals of different frequencies.

For example, referring to FIG. 11, the control words from control word RW01 to control word RW1D may be the second control word CW2. Referring to FIG. 11, four second control words CW2-1, CW2-2, CW2-3, and CW2-4 are illustrated. The four second control words CW2-1, CW2-2, CW2-3, and CW2-4 may store parameters corresponding to clock signals of different frequencies, respectively. The four second control words CW2-1, CW2-2, CW2-3, and CW2-4 may store a delay value for delaying the clock signals at different frequencies, respectively.

In some embodiments, each of the second control words CW2-1, CW2-2, CW2-3, and CW2-4 may be composed of or include a plurality of control words.

For example, referring to FIG. 11, an implementation example, in which each of the second control words CW2-1, CW2-2, CW2-3, and CW2-4 include a total of 7 control words, is shown.

Referring to FIG. 11, the 2-1st control word CW2-1 may be composed of or include control words from control word RW01 to control word RW07. The control word RW01 may be set as information about whether to delay a clock signal of the corresponding frequency. The control word RW02 may be set to the driving strength of the output clock signal of the clock driver 120. The control word RW03 may be set to a differential slew rate of the output clock signal. The control words from the control word RW04 to the control word RW07 may be set to a delay value of four differential output clock signal pairs such as the first differential output clock signal pair QCK0_A_t and QCK0_A_c, the second differential output clock signal pair QCK1_A_t and QCK1_A_c, the third differential output clock signal pair QCK0_B_t and QCK0_B_c, and the fourth differential output clock signal pair QCK1_B_t and QCK1_B_c. As in the above description, the other second control words CW2-2, CW2-3, and CW2-4 may also be composed of the same content.

In some embodiments, the first control word CW1 may be composed of or include one control word. The first control word CW1 may be identical to the first control word CW1 of FIG. 10.

In some embodiments, the third control word CW3 may be composed of at least one control word. The third control word CW3 may be identical to the third control word CW3 of FIG. 8.

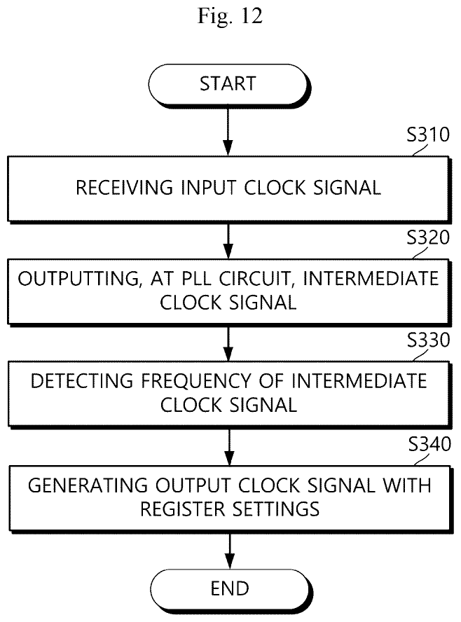

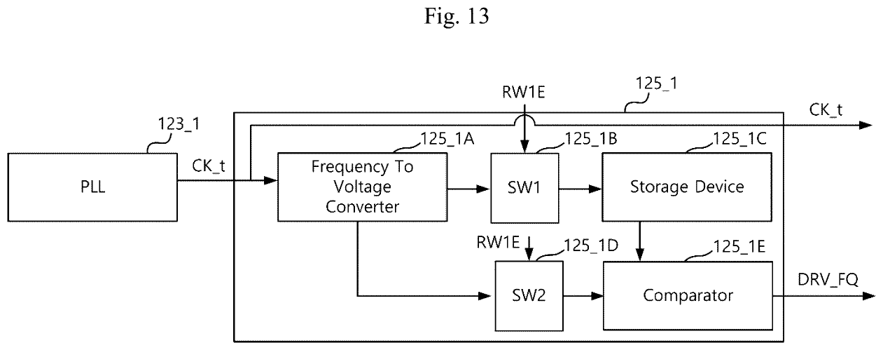

FIG. 12 is a flowchart showing an operating method of a memory module, according to some embodiments of the present disclosure. An operating method of FIG. 12 may be performed by the memory module 100 of FIG. 1. The operating method of FIG. 12 may be performed during a normal operation of the memory module 100. For example, it may be performed during data read and/or write operations of the memory system 10. The operating method of the memory module 100 is described with reference to FIGS. 12 and 13. Detailed descriptions of parts identical or similar to those described with reference to FIGS. 1 to 11 will be omitted.

In operation S310, the memory module 100 may receive an input clock signal from a memory controller. The input clock signal may be a clock signal of a specific frequency. During the training operation using the input clock signal, a bit position corresponding to the control mode of the frequency of the input clock signal may have already been set to “enable” in the first control word CW1 of FIG. 10.

In operation S320, the PLLs 123_1 and 123_2 of FIG. 6 may receive an input clock signal and may output an intermediate clock signal.

For example, referring to FIG. 13, the PLL 123_1 may transmit an intermediate clock signal CK_t to the frequency detector 125_1.

In operation S330, each of the frequency detectors 125_1 and 125_2 of FIG. 6 may compare the detected frequency with reference values stored in advance with respect to a plurality of driving frequencies. Operation S330 may be performed during the normal operation of the memory module 100.

For example, referring to FIG. 13, the frequency detector 125_1 may convert the intermediate clock signal CK_t into a voltage value, and a comparator circuit 125_1E may compare the converted voltage value with at least one voltage value stored in a storage device 125_1C. As the comparison result, the frequency detectors 125_1 and 125_2 may output the frequency DRV_FQ corresponding to the matching voltage value. The register read circuits 126_1 and 126_2 may read out the second control word CW2 from the register 121 based on the frequency DRV_FQ.

For example, when the frequency DRV_FQ corresponding to the matching voltage value is a first frequency, the frequency detectors 125_1 and 125_2 may read out the second control word CW2 corresponding to the first frequency among the plurality of second control words CW2. The register read circuit 126_1 of FIG. 6 may read out the second control word CW2 corresponding to the frequency DRV_FQ from the register 121.

In some embodiments, the frequency detectors 125_1 and 125_2 of FIG. 6 may include switching circuits 125_1B and 125_1D. Each of the switching circuits 125_1B and 125_1D may be turned on or off based on the first control word CW1.

For example, when one of the bit positions corresponding to the training mode of the first control word CW1 is set to “enable”, the first switching circuit 125_1B may be turned on. When one of the bit positions corresponding to the training mode of the first control word CW1 is set to “disable”, the second switching circuit 125_1D may be turned on. Accordingly, a voltage value obtained by converting the detected frequency value may be transmitted to the storage device 125_1C during a training operation, and may be transmitted to the comparator circuit 125_1E during a normal operation.

In operation S340, the clock trees 127_1, 127_2, 127_3, 127_4 of FIG. 6 may generate an output clock signal, which is obtained by applying a delay value corresponding to a driving frequency that is the same as the detected frequency, based on the second control word CW2.

In the meantime, the above description refers to detailed embodiments for carrying out the present disclosure. In addition to embodiments described above, the present disclosure may also include embodiments that are capable of being simply redesigned or easily modified. In addition, technologies that are easily changed and implemented by using the above embodiments may be included in the present disclosure. While the present disclosure has been described with reference to embodiments described above, it will be apparent to those of ordinary skill in the art that various changes and modifications may be made thereto without departing from the spirit and scope of the present disclosure as set forth in the following claims. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, steps, operations, elements and/or components, but do not preclude the presence or addition of one or more other features, steps, operations, elements, components and/or groups thereof. The term “and/or” includes any and all combinations of one or more of the associated listed items. The term “connected” may be used herein to refer to a physical and/or electrical connection and may refer to a direct or indirect physical and/or electrical connection.

According to various embodiments of the present disclosure, a memory module may operate stably even when the frequency of the received clock signal dynamically changes.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A method for training a memory device, the method comprising:
performing an initialization operation of the memory device; and
performing a training operation of the memory device by using clock signals of a plurality of driving frequencies,
wherein the performing of the training operation comprises:
setting bits in bit positions in a first control word of a register of a clock driver of the memory device, wherein the bit positions are associated with a control mode and a training mode of a clock signal which is being trained from among the clock signals;
performing a training operation to determine a parameter, which is capable of being set, from among a plurality of parameters of the memory device, based on the clock signal being trained, wherein the clock signal comprises a driving frequency of the plurality of driving frequencies; and
storing the parameter in a second control word of the register of the clock driver.

2. The method of claim 1, wherein the performing of the training operation comprises:
performing a training operation by using a first clock signal of a first driving frequency among the clock signals of the plurality of driving frequencies; and
performing a training operation by using a second clock signal of a second driving frequency among the clock signals of the plurality of driving frequencies.

3. The method of claim 1, wherein the first control word comprises a plurality of bit positions including the bits in the bit positions that were set,
wherein in the first control word, a first bit position associated with a control mode of a first clock signal of a first driving frequency is set to enable or disable,
wherein in the first control word, a second bit position associated with a control mode of a first clock signal of a second driving frequency is set to enable or disable,
wherein in the first control word, a third bit position associated with a training mode of the first clock signal of the first driving frequency is set to enable or disable, and
wherein in the first control word, a fourth bit position associated with a training mode of the first clock signal of the second driving frequency is set to enable or disable.

4. The method of claim 1, further comprising:
prior to the performing of the training operation, setting a bit position in the first control word associated with the training mode of the clock signal of the driving frequency that is being trained to enable; and
after the performing of the training operation, setting a bit position in the first control word associated with the training mode of the clock signal of the driving frequency that is being trained to disable.

5. The method of claim 1, wherein the performing of the initialization operation comprises:
in a third control word of the register of the clock driver, determining whether the clock driver supports the clock signals of the plurality of driving frequencies.

6. The method of claim 5, wherein the performing of the initialization operation further comprises:
checking a number of the clock signals of the plurality of driving frequencies supported by the clock driver in the third control word of the register of the clock driver.

7. The method of claim 5, wherein the third control word is set to be read only.

8. The method of claim 6, wherein the performing of the training operation is repeated for each of the clock signals of the plurality of driving frequencies supported by the clock driver.

9. The method of claim 1, wherein the storing of the parameter comprises:
storing a first parameter of a first clock signal of a first driving frequency and a second parameter of a second clock signal of a second driving frequency in different control words of the register of the clock driver, and
wherein the clock signals of the plurality of driving frequencies include the first clock signal of the first driving frequency and the second clock signal of the second driving frequency.

10. The method of claim 1, wherein the clock driver receives an input clock signal and outputs at least one output clock signal obtained by delaying the input clock signal.

11. The method of claim 10, wherein the storing of the parameter comprises:
storing a delay value of the input clock signal corresponding to the clock signal of the driving frequency being trained, in the second control word of the register of the clock driver.

12. A memory module comprising:
a plurality of memory devices; and
a clock driver device configured to receive an input clock signal and configured to transmit at least one output clock signal which is obtained by delaying the input clock signal, to the plurality of memory devices,
wherein the clock driver device comprises:
a register configured to store at least one control word of the clock driver device;
a PLL circuit configured to receive the input clock signal and to output an intermediate clock signal;
a frequency detection circuit configured to detect a frequency of the intermediate clock signal; and
a clock tree circuit configured to delay the intermediate clock signal based on the at least one control word associated with the frequency that was detected in the register, and
wherein the register is configured to store a delay value of each of clock signals of a plurality of driving frequencies in different control words.

13. The memory module of claim 12, wherein the register is configured to store a first control word comprising a plurality of first bit positions, and
wherein the first control word includes activation information of a control mode and a training mode of each of the clock signals of the plurality of driving frequencies.

14. The memory module of claim 13, wherein the register is configured to store a plurality of second control words, each comprising a plurality of second bit positions, and
wherein the plurality of second control words include delay values corresponding to the clock signals of the plurality of driving frequencies of the intermediate clock signal, respectively.

15. The memory module of claim 14, wherein the clock tree circuit is configured to delay the intermediate clock signal based on a second word corresponding to the frequency that was detected among the second control words.

16. The memory module of claim 13, wherein the frequency detection circuit comprises:
a frequency-to-voltage converter configured to receive the intermediate clock signal and to convert the intermediate clock signal into a voltage signal;
a storage device configured to store the voltage signal; and
a comparator circuit configured to compare the voltage signal output from the frequency-to-voltage converter with the voltage signal stored in the storage device.

17. A method for operating a memory module, the method comprising:
receiving an input clock signal from a memory controller;
receiving, by a PLL circuit, the input clock signal and outputting an intermediate clock signal;
detecting a frequency of the intermediate clock signal;
comparing the detected frequency with reference values stored in advance with respect to each of a plurality of driving frequencies; and
generating an output clock signal, which is obtained by applying a delay value corresponding to a driving frequency that is identical to the detected frequency.

18. The method of claim 17, wherein the comparing of the detected frequency with the reference values comprises:
converting the detected frequency into a first voltage; and
comparing the first voltage with second voltages respectively associated with respective clock signals of the plurality of driving frequencies.

19. The method of claim 18, wherein the second voltages are stored in a capacitor.

20. The method of claim 17, wherein the generating of the output clock signal comprises:
generating the output clock signal based on one of control words storing delay values for
respectively delaying the clock signals of the plurality of driving frequencies.
